(19) United States
(12) Patent Application Publication
(10) Pub. No.: US 2026/0141940 A1
(43) Pub. Date: May 21, 2026

(54) MEMORY SYSTEM, MEMORY CONTROLLER AND MEMORY DEVICE

(71) Applicant: Samsung Electronics Co., Ltd., Suwon-si (KR)

(72) Inventors: Jinsol Park, Suwon-si (KR); Reum Oh, Suwon-si (KR); Kijun Lee, Suwon-si (KR); Sunghye Cho, Suwon-si (KR); Myungkyu Lee, Suwon-si (KR); Eunae Lee, Suwon-si (KR)

(21) Appl. No.: 19/225,407

(22) Filed: Jun. 2, 2025

(30) Foreign Application Priority Data
Nov. 20, 2024 (KR) 10-2024-0165887

(51) Int. Cl. G11C 11/406

(52) U.S. Cl. CPC G11C 11/40618; G11C 11/40615; G11C 11/40626

(57) ABSTRACT

A memory system includes a memory device, a control circuit, and a memory controller. The memory device includes a plurality of memory regions, a candidate register set storing a plurality of candidate parameter sets corresponding to temperature ranges, respectively, a mode register set storing a temperature range and a refresh management parameter set. The control circuit stores, based on the temperature range, a first candidate parameter set of the plurality of candidate parameter sets as the refresh management parameter set in the mode register set. The memory controller obtains the refresh management parameter set from the memory device, based on an updated temperature range, counts activation counts of the plurality of memory regions, and provides a refresh management command to the memory device based on the activation counts and the refresh management parameter set.

### CROSS-REFERENCE TO RELATED APPLICATION(S)

This application claims the benefit under 35 USC 119(a) of Korean Patent Application No. 10-2024-0165887 filed on Nov. 20, 2024, in the Korean Intellectual Property Office, the entire disclosure of which is incorporated herein by reference.

### BACKGROUND

In general, Dynamic Random Access Memory (DRAM) performs a refresh operation to maintain data stored in a cell capacitor. As process technology advances, the integration of memory cells increases and the gap between memory cells gradually narrows. As the gap between memory cells narrows, the interference caused by adjacent memory cells or word lines increases the impact on the memory cell. If interference is concentrated on a specific memory cell, a row hammer may occur in which data stored in an adjacent memory cell changes.

### SUMMARY

Example implementations provide a memory device, a memory controller, and a memory system that enable a memory controller to timely control a target refresh operation of the memory device.

According to example implementations, a memory system includes a memory device including a plurality of memory regions, a candidate set storing a plurality of candidate parameter sets corresponding to temperature ranges, respectively, a mode register set storing a temperature range and a refresh management parameter set, and a control logic circuit storing, based on the temperature range, a first candidate parameter set of the plurality of candidate parameter sets as the refresh management parameter set in the mode register set; and a memory controller obtaining the refresh management parameter set from the memory device, based on an updated temperature range, counting activation counts of the plurality of memory regions, and providing a refresh management command to the memory device based on the activation counts and the refresh management parameter set.

According to example implementations, a memory controller includes a refresh management circuit configured to provide an activation command to a memory device and count activation counts of a plurality of memory regions, respectively, of the memory device; and a memory configured to store an activation count threshold value of the activation counts. The refresh management circuit is configured to receive a temperature range from the memory device, receive a revised count threshold value from the memory device based on an update to the temperature range, update the activation count threshold value stored in the memory based on the received count threshold value, to provide an updated activation count threshold value and provide a refresh management command for a target memory region of the plurality of memory regions, based on the activation count reaching the updated activation count threshold value.

According to example implementations, a memory device includes a plurality of memory regions having a plurality of memory cells; a register storing a plurality of candidate parameter sets corresponding to a plurality of temperature ranges, respectively; a mode register set storing a first temperature range in a first register area and a refresh management parameter set in a second register area; and a control circuit storing a first candidate parameter sets, of the plurality of candidate parameter sets, as the refresh management parameter set in the second register area based on the first temperature range, outputting the first temperature range based on a first read request for the first register area, and outputting the refresh management parameter set based on a second read request for the second register area.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating a memory system according to some example implementations;

FIG. 2 is a block diagram illustrating a memory device according to some example implementations;

FIG. 3 is a diagram illustrating a refresh management command;

FIG. 4 is a diagram illustrating a mode register;

FIG. 5 is a diagram illustrating a portion of a memory device according to some example implementations;

FIG. 6 is a diagram illustrating a refresh management circuit according to some example implementations;

FIG. 7 is a ladder diagram illustrating the interaction of a memory controller and a memory device according to some example implementations;

FIG. 8 is a diagram illustrating a memory module according to some example implementations; and

FIG. 9 is a diagram illustrating a semiconductor package including a stack semiconductor chip according to some example implementations.

### DETAILED DESCRIPTION

Hereinafter, some example implementations will be described with reference to the attached drawings.

The present disclosure relates to a memory device, a memory controller controlling the memory device, and a memory system including the memory device.

To prevent the row hammer, a target refresh operation may be performed on a designated memory region of a memory device. Using a refresh management (RFM) interface, a memory controller may determine a target memory region and may set a time for target refresh of the target memory region.

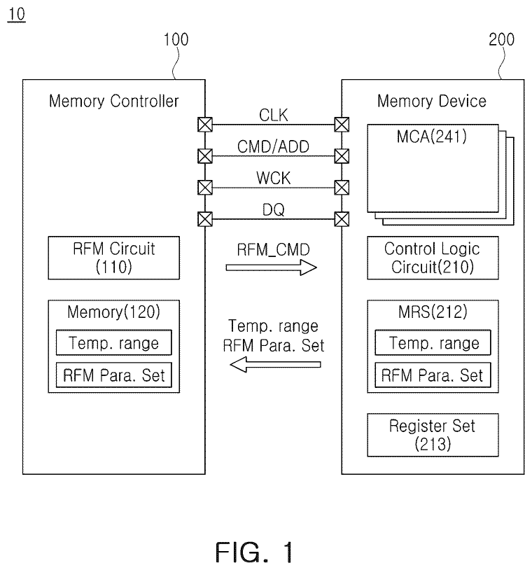

FIG. 1 is a drawing illustrating a memory system according to some example implementations.

Referring to FIG. 1, a memory system 10 may include a memory device 200 and a memory controller 100 that controls the memory device 200.

The memory system 10 may be implemented to be included in a personal computer (PC) or a mobile electronic device. The mobile electronic device may be implemented as a laptop computer, a mobile phone, a smart phone, a tablet PC, a Personal Digital Assistant (PDA), an Enterprise Digital Assistant (EDA), a digital still camera, a digital video camera, a Portable Multimedia Player (PMP), a Personal Navigation Device or Portable Navigation Device (PND), a handheld game console, a Mobile Internet Device (MID), a wearable computer, an Internet of Things (IoT) device, an Internet of Everything (IoE) device, or a drone.

The memory device 200 may store data. In some example implementations, the memory device 200 may be implemented as a volatile memory device. For example, the volatile memory device may be implemented as a Random Access Memory (RAM), a Dynamic RAM (DRAM), a Static RAM (SRAM), or a Low Power Double Data Rate (LPDDR) DRAM.

The memory controller 100 may be implemented to control the memory device 200 to read data stored in the memory device 200 or to write data to the memory device 200. The memory controller 100 may control a write operation or a read operation for the memory device 200 by providing a command CMD and an address ADDR to the memory device 200 in synchronization with a clock CLK. In addition, data input/output to the data lines DQ may be transmitted and received between the memory controller 100 and the memory device 200 in synchronization with a data transfer clock WCK.

In addition, the memory controller 100 may provide interfacing between the host and the memory device 200. The memory controller 100 may exchange data and signals with the memory device 200 through a clock signal line CLK, a command/address line CMD/ADD, a data transfer clock signal line WCK, data lines DQ, and the like.

The memory device 200 may include memory cell arrays 241, a control logic circuit 210, a mode register set 212, and a register set 213.

Each of the memory cell arrays 241 may include a plurality of memory cells connected to word lines and bit lines.

The control logic circuit 210 may control the memory device 200 as a whole. For example, the control logic circuit 210 may control read operations, write operations, and refresh operations for the memory cell arrays 241.

The mode register set 212 may include a plurality of mode registers that store values for setting an operation mode. In detail, the mode register set 212 may store parameters for controlling the refresh operation.

The memory device 200 may store data by storing charges in memory cells. In the case of a volatile memory device, as time passes, the charges stored in the memory cells decrease due to leakage current, or the like, and the data stored in the memory cells may be lost.

A refresh operation may refer to an operation of restoring data before the data stored in a memory cell is lost. For example, if data values of a row including memory cells to be refreshed are loaded into a sense amplifier, the data stored in the memory cells may also be refreshed.

The time from when data is written to a memory cell until the data is lost and cannot be read may be referred to as a retention time. The refresh operation should be performed on the memory cells before the retention time of each of the memory cells of the memory device 200 elapses so that the data may be maintained. A refresh operation that is periodically performed on all memory cells may be referred to as a normal refresh operation. The memory controller 100 may provide a normal refresh command to the memory device 200 so that all memory cells may be periodically refreshed.

For example, the memory controller 100 may provide one normal refresh command to the memory device 200 every refresh interval time tREFIe. The memory controller 100 may guarantee the memory device 200 a time equal to a refresh cycle time tRFC for each normal refresh command. For example, the memory controller 100 may not provide another command to the memory device 200 during the refresh cycle time tRFC. The memory device 200 may perform a refresh operation on the memory cells within the retention time by utilizing the refresh cycle time tRFC.

The retention time of the memory cell may vary depending on the temperature of the memory device 200. For example, as the temperature of the memory device 200 increases, the amount of leakage current increases and the retention time may be shortened. The refresh interval time tREFIe, which is the cycle during which the normal refresh operation is performed, may be determined depending on a temperature range of the memory device 200. For example, the higher the temperature range of the memory device 200, the shorter the refresh interval time tREFIe may be.

If a row is activated multiple times in the memory device 200, a row hammer may occur in which data stored in adjacent rows changes. Rows are periodically refreshed through a normal refresh operation, but if a row is activated too many times between the cycles in which the normal refresh operation is performed, a row hammer may occur in adjacent rows. To prevent the row hammer, a refresh operation performed in a target area based on the number of activations of rows may be referred to as a target refresh operation. For example, the memory device 200 may perform a normal refresh operation during the refresh cycle time tRFC and perform a target refresh operation in the remaining time.

As the integration of memory cells increases, the gap between memory cells is gradually narrowing. The row hammer is getting worse due to the narrowing of the gap between memory cells. To maintain data despite the worsening row hammer, the memory device 200 may require a relatively longer time to perform a target refresh operation.

To provide sufficient time for the memory device 200 to perform the target refresh operation, a refresh management (RFM) interface may be provided. The memory controller 100 may provide additional time for the target refresh operation by providing a refresh management command RFM_CMD to the memory device 200 based on the activation count of the memory regions. The refresh management command may also be referred to as an RFM command.

The memory controller 100 may guarantee the memory device 200 a time equal to the refresh management time tRFM for each refresh management command. The memory device 200 may perform a target refresh operation at a refresh management time tRFM.

The memory controller 100 may determine whether to provide a refresh management command RFM_CMD to the memory device 200 based on activation counts of the memory regions and a set of refresh management parameters associated with the activation counts.

For example, the memory controller 100 may include a refresh management circuit 110 and a memory 120. The refresh management circuit 110 may count an activation count for each of the memory regions of the memory device 200 and provide a refresh management command RFM_CMD to the memory device 200 based on the activation count. The activation count may also be referred to as a rolling accumulated activation (RAA) count.

The memory 120 may store a refresh management parameter set obtained from a mode register set 212. The refresh management parameter set may define a threshold value of the activation count and control the activation count.

If the refresh management parameter set is fixed regardless of the temperature of the memory device 200, it may be difficult for the target refresh operation to be performed in a timely manner in relation to the normal refresh operation performed at each refresh interval time tREFIe determined according to the temperature range.

For example, the refresh management command may be set to be skipped when the refresh interval time tREFIe is shorter than the time determined based on the threshold value of the activation count. If the refresh management parameter set is fixed, the refresh management command may be skipped in a high temperature environment where the normal refresh operation is performed in a short cycle, and it may be difficult to prevent the row hammer of a specific memory region.

On the other hand, in a low temperature environment where the normal refresh operation is performed in a long cycle, the target refresh operation may be performed relatively frequently, so that the time for performing other commands may be reduced. In detail, the processing efficiency of the memory system 10 may be reduced.

According to some example implementations of the present disclosure, a refresh management parameter set may be dynamically adjusted according to the temperature of the memory device 200, and a target refresh operation cycle may be dynamically controlled.

The memory device 200 may store candidate parameter sets respectively corresponding to a plurality of temperature ranges in the register set 213. Based on the current measured temperature range, the memory device 200 may store one of the candidate parameter sets as a refresh management parameter set in the mode register set 212.

When the measured temperature range is updated, the memory controller 100 may obtain the refresh management parameter set stored in the mode register set 212, update the refresh management parameter set of the memory 120, and control the target refresh operation based on the updated refresh management parameter set.

According to some example implementations, the memory device 200 may perform the target refresh operation in a timely manner in relation to the normal refresh operation whose cycle varies according to the temperature. Accordingly, while data stored in the memory device 200 may be protected from the row hammer, performance degradation of the memory system 10 may be significantly reduced.

Below, before the memory system 10 according to some example implementations is described in detail, the structure of the memory device 200 is described in detail.

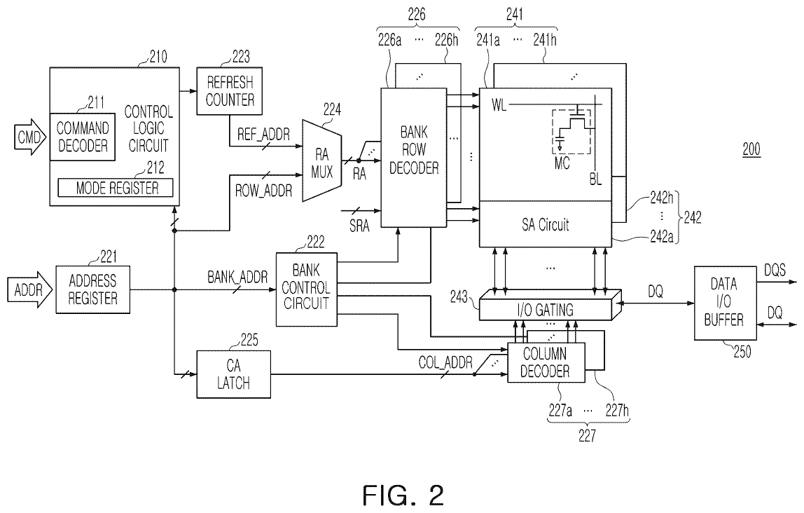

FIG. 2 is a block diagram illustrating a memory device according to some example implementations.

Referring to FIG. 2, the memory device 200 may include a control logic circuit 210, an address register 221, a memory bank control circuit 222, a refresh counter 223, a row address multiplexer 224, a column address latch 225, a row decoder 226, a column decoder 227, a memory cell array 241, a sense amplifier 242, an input/output gate circuit 243, and a data input/output buffer 250.

The control logic circuit 210 may control the operation of the memory device 200. For example, the control logic circuit 210 may generate control signals so that the memory device 200 performs a read operation, a write operation, a refresh operation, and the like. For example, the control logic circuit 210 may generate a control signal for an activation operation for the read operation, the write operation, and the refresh operation.

The control logic circuit 210 may include a command decoder 211 that decodes a command CMD received from a memory controller 100, a mode register set 212 for setting an operation mode of the memory device 200, and a register set 213 for storing data related to the operation of the memory device 200.

For example, the command decoder 211 may decode a write enable signal, a row address strobe signal, a column address strobe signal, a chip select signal, and the like to generate the control signals corresponding to the command CMD.

The memory cell array 241 may include a plurality of memory cell arrays 241 (241a to 241h). In addition, a plurality of row decoders 226 (226a to 226h), a plurality of column decoders 227 (227a to 227h), and a plurality of sense amplifiers 242 (242a to 242h) may be connected to a plurality of memory cell arrays 241a to 241h, respectively.

A plurality of memory cell arrays 241a to 241h, a plurality of column decoders 227a to 227h, a plurality of row decoders 226a to 226h, and a plurality of sense amplifiers 242a to 242h may respectively configure a plurality of memory banks.

A plurality of memory cell arrays 241a to 241h may include a plurality of word lines, a plurality of bit lines, and a plurality of memory cells connected to the plurality of word lines and the plurality of bit lines. Memory cells connected to one word line may be referred to as a memory cell row.

A plurality of sense amplifiers 242a to 242h may detect voltage changes of the plurality of bit lines and amplify the voltage changes. For example, in response to an activation command, a memory cell row included in a memory bank may be activated so that data stored in the memory cell row may be transferred to the sense amplifier.

An address register 221 may receive an address ADDR including a memory bank address BANK_ADDR, a row address ROW_ADDR, and a column address COL_ADDR from a memory controller connected to a memory device 200. The address register 221 may provide the received memory bank address BANK_ADDR to the memory bank control circuit 222, provide the received row address ROW_ADDR to the row address multiplexer 224, and provide the received column address COL_ADDR to the column address latch 225.

The memory bank control circuit 222 may generate memory bank control signals in response to the memory bank address BANK_ADDR. In response to the memory bank control signals, a row decoder corresponding to the memory bank address BANK_ADDR among the plurality of row decoders 224a to 224h may be activated, and a column decoder corresponding to the memory bank address BANK_ADDR among the plurality of column decoders 227a to 227h may be activated.

The row address multiplexer 224 may receive a row address ROW_ADDR from the address register 221 and a refresh row address REF_ADDR from the refresh counter 223. The row address multiplexer 224 may selectively output the row address ROW_ADDR or the refresh row address REF_ADDR as the row address RA. The row address RA output from the row address multiplexer 224 may be applied to each of the plurality of row decoders 226a to 226h.

The refresh counter 223 may sequentially increase or decrease the refresh row address REF_ADDR according to the control of the control logic circuit 210.

Among the plurality of row decoders 226a to 226h, a row decoder activated by the memory bank control circuit 222 may decode a row address RA output from a row address multiplexer 224 and activate a word line corresponding to the row address. For example, the activated row decoder may apply a word line driving voltage to a word line corresponding to the row address.

The column address latch 225 may receive a column address COL_ADDR from the address register 221 and temporarily store the received column address COL_ADDR. In addition, the column address latch 225 may incrementally increase the received column address COL_ADDR in a burst mode. The column address latch 225 may apply the temporarily stored or incrementally increased column address COL_ADDR to each of the plurality of column decoders 227a to 227h.

Among the plurality of column decoders 227a to 227h, a column decoder activated by the memory bank control circuit 222 may activate a sense amplifier corresponding to the memory bank address BANK_ADDR and the column address COL_ADDR through a corresponding input/output gating circuit 243.

The input/output gating circuit 243 may include circuits for gating input/output data, input data mask logic, read data latches for storing data output from a plurality of memory cell arrays 241a to 241h, and write drivers for writing data to a plurality of memory cell arrays 241a to 241h.

A data signal DQ to be read from one of the plurality of memory cell arrays 241a to 241h may be detected by a sense amplifier corresponding to the one memory cell array and stored in the read data latches. The data signal DQ stored in the read data latches may be provided to a memory controller together with a data strobe signal DQS.

A data signal DQ to be written to a memory cell array MCA included in one of the plurality of memory cell arrays 241a to 241h may be provided to the input/output gating circuit 243 by a data input/output buffer 250. The input/output gating circuit 243 may write the data signal DQ to the target page of the one memory cell array MCA through the write drivers.

The data input/output buffer 250 may provide the data signal DQ to the input/output gating circuit 243 in a write operation, and may provide the data signal DQ provided from the input/output gating circuit 243 to the memory controller in a read operation.

According to some example implementations, the mode register set 212 may store a refresh management parameter set associated with a refresh management command and a measured temperature range. Although omitted in FIG. 2, the memory device 200 may further include a temperature sensor that detects the temperature of the memory device 200 to determine the measured temperature range.

The register set 213 may include candidate parameter sets respectively corresponding to a plurality of temperature ranges. The control logic circuit 210 may store one of the plurality of candidate parameter sets as the refresh management parameter set in the mode register set 212 based on the measured temperature range.

According to some example implementations, the memory device 200 may provide a measured temperature range in response to a request from the memory controller 100 as described with reference to FIG. 1 and may provide a refresh management parameter according to the measured temperature range. The memory device 200 may perform a target refresh operation in a timely manner by obtaining a refresh management time tRFM according to the measured temperature range from the memory controller 100.

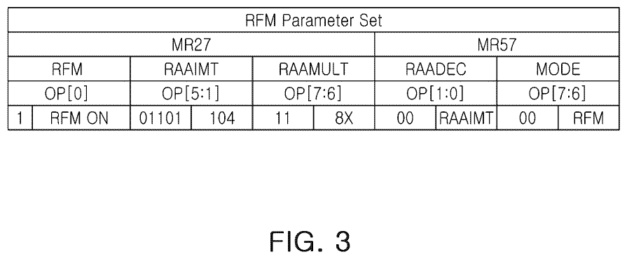

FIG. 3 is a diagram illustrating a refresh management parameter.

Referring to FIG. 3, the refresh management parameter set (RFM parameter set) may include Refresh Management (RFM), rolling accumulated activation initial management threshold (RAAIMT), and rolling accumulated activation multiplier (RAAMULT) stored in the MR27 area of the mode register, and rolling accumulated activation decrement (RAADEC) and MODE stored in the MR57 area of the mode register.

The cycle at which the refresh management command is provided from the memory controller 100 to the memory device 200 may be adjusted according to RAAIMT and RAAMULT. In detail, the memory controller 100 performs an activation count for each of the memory regions of the memory device 200, and when a target memory region whose active count reaches a count threshold is detected, the memory controller 100 may provide a refresh management command for the target memory region to the memory device 200.

RAAIMT may be a unit threshold value for refresh management, and RAAMULT may be a multiplier value multiplied by the unit threshold value. The count threshold value may be determined as a product of the unit threshold value RAAIMT and the multiplier value RAAMULT.

In some example implementations, the memory controller 100 may skip the operation of providing the refresh management command to the memory device 200 if the refresh management threshold time RFMTH, which is determined by the product of the unit threshold value RAAIMT and the activation time tRC, is greater than or equal to the refresh interval time tREFIe. The activation time tRC may be a predetermined parameter, which is a parameter obtained by adding a row precharge time and a row active time.

RAADEC may be a decrement of the activation count. For example, when the memory controller 100 provides the refresh management command for the target memory region to the memory device 200 once, the activation count of the target memory region may be decreased by the decrement RAADEC.

RFM may indicate whether the refresh management is on or off, and MODE may indicate the mode of the refresh management.

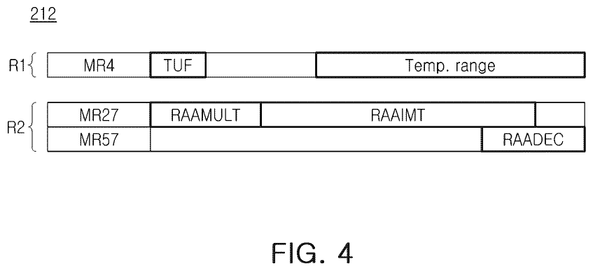

FIG. 4 is a diagram illustrating a mode register.

The mode register set 212 may include a plurality of mode registers to define various operation modes of the memory device 200. FIG. 4 illustrates mode registers of MR4, MR27, and MR57 among multiple mode registers.

The mode register MR4 may store a measured temperature range (Temp. range) and a temperature update flag TUF. The memory device 200 may determine a refresh rate of a normal refresh operation, for example, a refresh interval time tREFIe, based on the temperature range stored in the mode register MR4. The refresh rate according to the temperature range may be determined in advance. For example, the higher the measured temperature range, the shorter the refresh interval time tREFIe may be, so that the normal refresh operation may be performed in a shorter cycle as the current temperature of the memory device 200 increases.

The temperature update flag TUF may indicate whether the measured temperature range has been updated after the measured temperature range is provided to the memory controller 100. For example, the temperature update flag TUF may have a first state when the measured temperature range is provided to the memory controller 100, and may have a second state when the measured temperature range is updated in the mode register MR4.

The mode register MR27 may store the multiplier RAAMULT and the unit threshold value RAAIMT described with reference to FIG. 3, and the mode register MR57 may store the decrement RAADEC described with reference to FIG. 3. According to some example implementations, the multiplier RAAMULT, the unit threshold value RAAIMT, and the decrement RAADEC may be stored in the mode registers MR27 and MR57 at the time of system initialization and may be updated based on the measured temperature range stored in the mode register MR4.

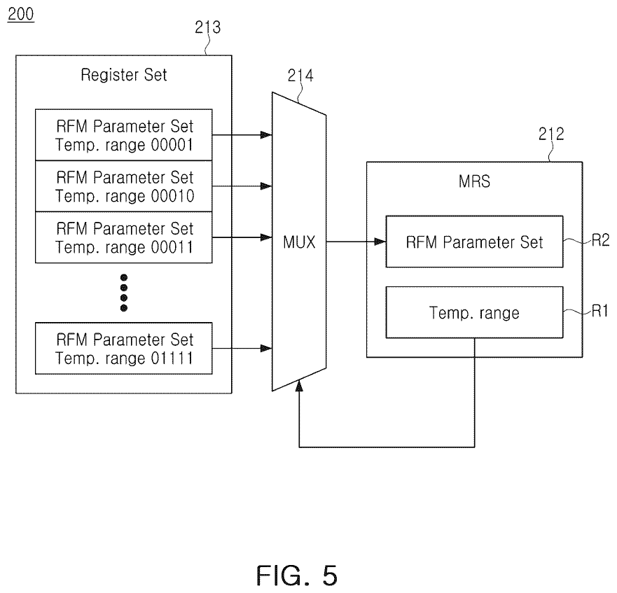

Hereinafter, a method for the memory device 200 to update a refresh management parameter set is described in detail with reference to FIG. 5.

FIG. 5 is a diagram illustrating a portion of a memory device according to some example implementations.

Referring to FIG. 5, the memory device 200 may include a mode register set 212, a register set 213, and a multiplexer 214.

The mode register set 212 may store a temperature range in a first register area R1 and a refresh management parameter set in a second register area R2. The first register area R1 may correspond to the mode register MR4 described with reference to FIG. 4, and the second register area R2 may correspond to the mode registers MR27 and MR57 described with reference to FIG. 4.

The register set 213 may store candidate parameter sets respectively corresponding to a plurality of temperature ranges.

In some example implementations, the candidate parameter set according to the temperature range may be experimentally determined. For example, for the respective temperature ranges that the first register area R1 may have, a refresh operation may be tested using multiple combinations of refresh management parameters, and a combination of refresh management parameters may be determined so that an indicator representing the degree of disturbance of memory cell rows and an indicator representing the efficiency of the memory system according to the length of the refresh management time tRFM may be optimized.

In some example implementations, the unit threshold value RAAIMT and the multiplier value RAAMULT may be determined so that the count threshold values have the same or a smaller value for a higher temperature range. In addition, the decrement RAADEC may be determined to have the same value or a higher value for a higher temperature range.

The multiplexer 214 may receive candidate parameter sets as input signals, receive a temperature range stored in the mode register circuit 212 as a selection signal, and output one of the candidate parameter sets as a refresh management parameter set according to the temperature range.

The mode register set 212, the register set 213, and the multiplexer 214 may be included in the control logic circuit 210, and may be implemented as a separate circuit from the control logic circuit 210.

The memory controller 100 may obtain a refresh management parameter set that is updated according to a temperature range from the memory device 200, and provide a refresh management command to the memory device 200 at a cycle determined based on the refresh management parameters.

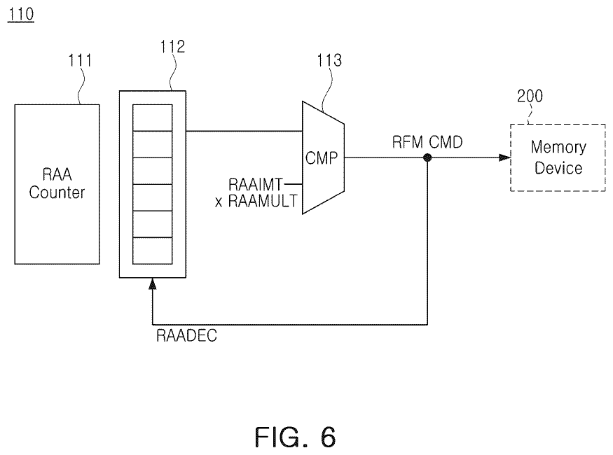

FIG. 6 is a diagram illustrating a refresh management circuit according to some example implementations.

Referring to FIG. 6, the refresh management circuit 110 included in the memory controller 100 described with reference to FIG. 1 may include an activation counter 111, a count register 112, and a comparator 113.

The activation counter 111 may count an activation count for each memory region. For example, one memory region may correspond to one memory bank. However, the present disclosure is not limited thereto, and the range of one memory region may vary.

The count register 112 may store activation counts of memory regions counted by the activation counter 111.

The comparator 113 may compare the activation counts stored in the count register 112 with a count threshold value. As described with reference to FIG. 3, the count threshold value may be determined as a product of a unit threshold value RAAIMT and a multiplier value RAAMULT. The comparator 113 may detect a target memory region among a plurality of memory regions whose activation count has reached the count threshold value.

The activation counter 111 may stop the activation count for the target memory region and prohibit providing the activation command for the target memory region to the memory device 200.

The comparator 113 may provide the memory device 200 with a refresh management command requesting a target refresh operation for the target memory region. In addition, the comparator 113 may decrease the activation count of the target memory region by RAADEC.

The refresh management parameter set such as RAAIMT, RAAMULT, and RAADEC used in the refresh management circuit 110 may be obtained from the memory 120 as described with reference to FIG. 1. The refresh management parameter set stored in the memory 120 may be updated according to the temperature change of the memory device 200.

Hereinafter, a method of operating a memory system is described, including a method of updating a refresh management parameter set by a memory controller 100.

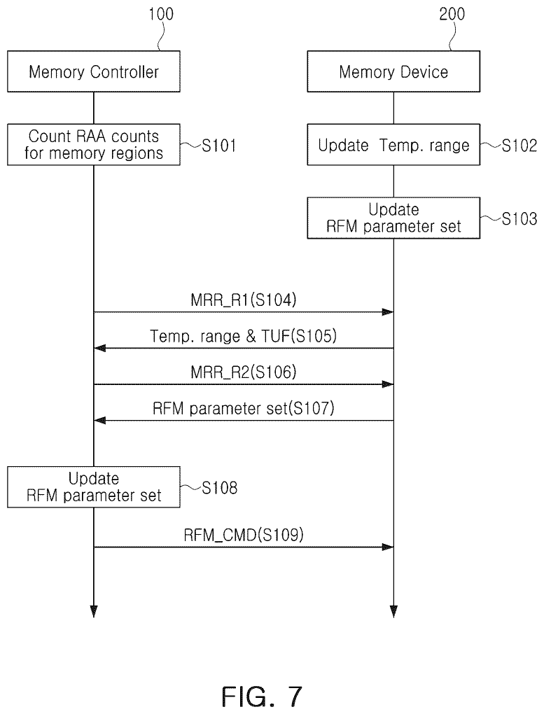

FIG. 7 is a ladder diagram illustrating the interaction of a memory controller and a memory device according to some example implementations.

The memory controller 100 and the memory device 200 of FIG. 7 may correspond to the memory controller 100 and the memory device 200 described with reference to FIG. 1.

In operation S101, the memory controller 100 may provide an activation command to memory regions and count activation counts for the memory regions. For example, the memory regions may each correspond to one memory bank of the memory device 200.

In operation S102, the memory device 200 may update a temperature range. For example, the memory device 200 may periodically measure the temperature using an internal temperature sensor, and if the measured temperature is out of the temperature range currently stored in the first register area R1, the temperature range stored in the first register area R1 may be changed. For example, the first register area R1 may correspond to the mode register MR4.

In operation S103, the memory device 200 may update the refresh management parameter set. According to some example implementations, the memory device 200 may store a parameter set corresponding to the updated temperature range among the candidate parameter sets stored in advance for respective temperature ranges, in the second register area R2, as the refresh management parameter set. For example, the second register area R2 may include mode registers MR27 and MR57.

In operation S104, the memory controller 100 may provide a first mode register read command MRR_R1 for the first register area R1 to the memory device 200. Operation S104 may be performed periodically.

In operation S105, the memory device 200 may provide the temperature range and the temperature update flag TUF stored in the first register area R1 to the memory controller 100 in response to the first mode register read command MRR_R1. In some example implementations, the memory controller 100 may control the normal refresh operation of the memory device 200 based on the temperature range acquired from the memory device 200.

If the temperature update flag TUF indicates that the temperature range is updated, the memory controller 100 may provide a second mode register read command MRR_R2 for the second register area R2 in operation S106.

In operation S107, the memory device 200 may provide the refresh management parameter set stored in the second register area R2 to the memory controller 100 in response to the second mode register read command MRR_R2.

In operation S108, the memory controller 100 may update the refresh management parameter set by storing the refresh management parameter set received from the memory device 200 in the internal memory.

In operation S109, the memory controller 100 may provide the refresh management command RFM_CMD to the memory device 200 based on the refresh management parameter set.

According to some example implementations, the memory controller 100 may control the target refresh operation of the memory device 200 based on a refresh management parameter set determined based on the temperature of the memory device 200. Accordingly, the data of the memory device 200 may be protected from the row hammer, while the efficiency reduction of the memory system due to the target refresh operation may be alleviated.

For example, the memory controller 100 may control the memory device 200 so that the normal refresh operation is performed in a shorter cycle as the temperature range of the memory device 200 is higher. In addition, as described with reference to FIG. 3, the memory controller 100 may skip the operation of providing the refresh management command to the memory device 200 if the refresh management threshold time RFMTH determined based on the unit threshold value RAAIMT is greater than or equal to the refresh interval time tREFIe.

According to some example implementations, the memory device 200 may have a unit threshold value RAAIMT and a multiplier value RAAMULT that make the count threshold value lower in a higher temperature range. For example, in a higher temperature range, a target refresh operation for the memory region may be performed even if a smaller number of activation counts are accumulated in the memory region. In addition, since the refresh management threshold time RFMTH may be shorter than the refresh interval time tREFIe, the target refresh operation may be prevented from being skipped due to a relatively frequently performed normal refresh operation. Accordingly, data may be protected from the row hammer when the memory device 200 is placed in a high temperature environment.

Conversely, in a lower temperature range, a target refresh operation for the memory region may be performed even if a larger number of activation counts are accumulated in the memory region. When the memory device 200 is placed in a low-temperature environment, the target refresh operation may be prevented from being performed too frequently, thereby reducing the processing efficiency of the memory system 10.

Hereinafter, devices to which the memory system according to some example implementations may be applied are described.

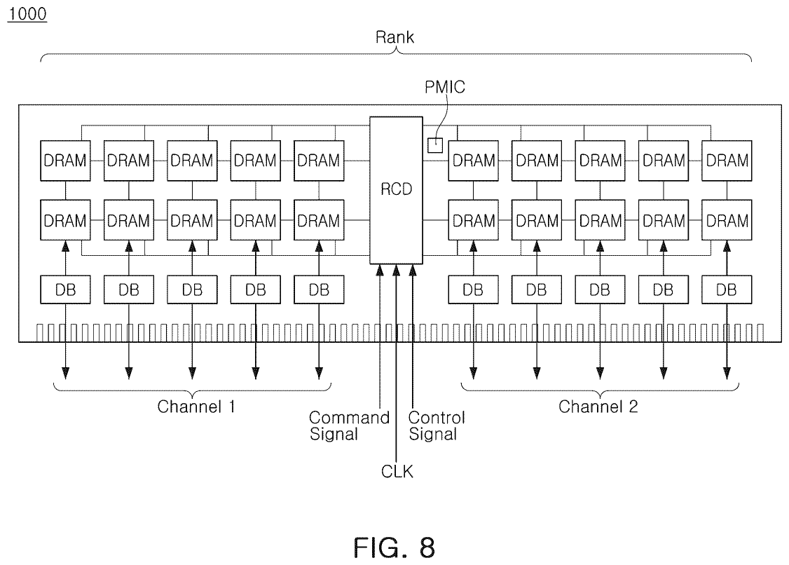

FIG. 8 is a drawing illustrating a memory module according to some example implementations by way of example.

FIG. 8 is a drawing illustrating a memory module 1000 according to some example implementations as an example. Referring to FIG. 8, the memory module 1000 may include a plurality of memory chips DRAMs each including a memory cell array, a buffer chip RCD for routing a transmission/reception signal with a memory controller or managing a memory operation for the memory chips, and a power management chip PMIC.

The RCD may control the memory chips DRAMs and the power management chip PMIC according to the control of the memory controller. For example, the RCD may receive a command signal, a control signal, and a clock signal from the memory controller. The memory chips DRAMs are respectively connected to a corresponding data buffer among data buffers DB through a corresponding data transmission line, and may transmit and receive data signals DQ and data strobe signals DQS.

The memory controller transmits commands to respective channels of the memory chip DRAM. Respective channels have independent commands, addresses, and buses so that they may operate in parallel with each other. One channel has one or more ranks, and each rank has an independent DRAM device. In addition, all ranks in the channel operate in parallel. Each rank has a number of memory banks, and DRAM cells are present in a two-dimensional array form in the memory banks. Respective memory banks may operate in parallel.

In some example implementations, the rank may include eight memory bank groups. Each of the memory bank groups may include four memory banks. In some example implementations, the memory chips may be divided into memory chips dedicated to the first channel and memory chips dedicated to the second channel.

According to some example implementations, each of a plurality of memory chips DRAMs may measure an internal temperature as described with reference to FIGS. 1 to 7, and update one candidate parameter set corresponding to a measured temperature range as a refresh management parameter set, from among candidate parameter sets corresponding to temperature ranges. The memory controller may obtain an updated refresh management parameter set from the memory chip in which the measured temperature range has been updated, and control a target refresh operation of the memory chip based on the refresh management parameter set and the activation counts of the memory regions.

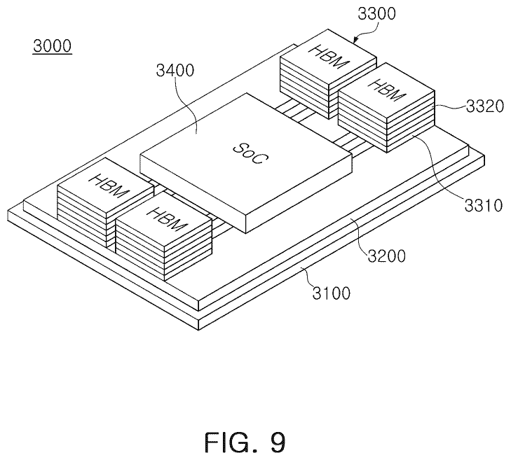

FIG. 9 is a drawing illustrating a semiconductor package including a stack semiconductor chip according to some example implementations.

Referring to FIG. 9, a semiconductor package 3000 may be a memory module including at least one stack semiconductor chip 3300 mounted on a package substrate 3100 such as a printed circuit board and a system-on-chip (SOC) 3400. An interposer 3200 may be optionally further provided on the package substrate 3100. The stack semiconductor chip 3300 may be formed as a Chip-on-Chip (CoC).

The stack semiconductor chip 3300 may include at least one memory chip 3320 stacked on a buffer chip 3310 such as a logic chip. The buffer chip 3310 and the at least one memory chip 3320 may be connected to each other by a through silicon via (TSV). The buffer chip 3320 may perform a training operation on the memory chip 3320. The stack semiconductor chip 3300 may be a high bandwidth memory (HBM).

The semiconductor package 300 according to some example implementations may dynamically change refresh management parameter sets that determine a trigger period of a refresh management command based on an internal temperature of the memory chip 3320. Accordingly, the semiconductor package 300 may improve the processing efficiency of the semiconductor package 300 while protecting data from the row hammer according to the internal temperature of the memory chip 3320. For example, the semiconductor package 300 may control the cycle of the normal refresh operation according to the internal temperature of the memory chip 3320, and may perform the target refresh operation at an optimized cycle in relation to the normal refresh operation cycle.

As set forth above, a memory device according to some example implementations may perform a normal refresh operation at different cycles depending on a temperature, and may provide a refresh management parameter set determined depending on the temperature to a memory controller.

A memory controller according to some example implementations may control the memory device so that a target refresh operation is performed in a timely manner depending on a temperature based on the refresh management parameter set. As a result, data of the memory device may be protected from a row hammer, while the performance efficiency of the memory system may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A memory system comprising:
a memory device comprising
a plurality of memory regions,
a candidate register set configured to store a plurality of candidate parameter sets corresponding to temperature ranges, respectively,
a mode register set configured to store a temperature range and a refresh management parameter set, and
a control logic circuit configured to store, based on the temperature range, a first candidate parameter set of the plurality of candidate parameter sets as the refresh management parameter set in the mode register set; and
a memory controller configured to
obtain the refresh management parameter set from the memory device, based on an updated temperature range,
count activation counts of the plurality of memory regions, and
provide a refresh management command to the memory device based on the activation counts and the refresh management parameter set.

2. The memory system of claim 1, wherein the refresh management parameter set comprises a rolling accumulated activation initial management threshold (RAAIMT), a RAA multiplier (RAAMULT), and a RAA decrement (RAADEC).

3. The memory system of claim 2, wherein the memory controller is configured to skip, based on a target refresh threshold, providing the refresh management command, wherein the target refresh threshold is based on a product of the RAAIMT and an activation time that is greater than a refresh interval of a normal refresh.

4. The memory system of claim 3, wherein the memory device is configured to perform, based on the temperature range, the normal refresh for the plurality of memory regions at different cycles.

5. The memory system of claim 3, wherein the memory device is configured to reduce, based on an increase in the temperature range, a cycle of the normal refresh for the plurality of memory regions.

6. The memory system of claim 2, wherein the mode register set comprises,
a first register area configured to store the temperature range,
a second register area configured to store the RAAIMT and RAAMULT, and
a third register area configured to store the RAADEC.

7. The memory system of claim 1, wherein the memory controller is configured to
provide a mode register read command for a first register area, and
receive the temperature range based on the mode register read command from the memory device, wherein the first register area is configured to store the temperature range.

8. The memory system of claim 7, wherein the memory controller is configured to receive a flag signal indicating that the temperature range has been updated.

9. The memory system of claim 1, wherein each memory region of the plurality of memory regions comprises a memory bank.

10. A memory controller, comprising:
a refresh management circuit configured to provide an activation command to a memory device and to count activation counts of a plurality of memory regions, respectively, of the memory device; and
a memory configured to store an activation count threshold value,
wherein the refresh management circuit is configured to
receive a temperature range from the memory device,
receive a revised count threshold value from the memory device based on an update to the temperature range,
update the activation count threshold value in the memory device, based on the revised count threshold value, to provide an updated activation count threshold value, and
provide a refresh management command for a target memory region, of the plurality of memory regions, based on the activation count reaching the updated activation count threshold value.

11. The memory controller of claim 10, wherein the memory is configured to store a count decrement of the activation counts, and
the refresh management circuit is configured to
receive an updated count decrement from the memory device based on an update to the temperature range,
revise the count decrement stored in the memory based on the updated count decrement to provide a revised count decrement, and
reduce, based on the refresh management command, the activation count of the target memory region by the revised count decrement.

12. The memory controller of claim 11, wherein the refresh management circuit is configured to
provide a mode register read command for a first register area, and
receive the temperature range, wherein the first register area is configured to store the temperature range to the memory device.

13. The memory controller of claim 11, wherein the revised count threshold value is based on a product of a unit threshold value and a multiplier value.

14. The memory controller of claim 13, wherein the refresh management circuit is configured to
provide a mode register read command for a second register area, and
subsequently receive, from the second register area, the unit threshold value, the multiplier value, and the count decrement.

15. The memory controller of claim 11, wherein the refresh management circuit is configured to prohibit an activation command for the target memory region based on the activation count having reached the updated activation count threshold value.

16. A memory device comprising:
a plurality of memory regions having a plurality of memory cells;
a register configured to store a plurality of candidate parameter sets corresponding to plurality of temperature ranges, respectively;
a mode register configured to store a first temperature range in a first register area and a refresh management parameter set in a second register area; and
a control logic circuit configured to
store a first candidate parameter set, of the plurality of candidate parameter sets, as the refresh management parameter set in the second register area based on the first temperature range,
output the first temperature range based on a first read request for the first register area, and
output the refresh management parameter set based on a second read request for the second register area.

17. The memory device of claim 16, wherein the refresh management parameter set includes a rolling accumulated activation initial management threshold (RAAIMT), a RAA multiplier, and a RAA decrement (RAADEC).

18. The memory device of claim 17, wherein a first RAAIMT corresponding to a first temperature range has a value less than or equal to a value of a second RAAIMT corresponding to a second temperature range, wherein the second temperature range is lower than the first temperature range.

19. The memory device of claim 17, wherein a first RAADEC corresponding to a first temperature range has a value greater than or equal to a value of a second RAADEC corresponding to a second temperature range, wherein the second temperature range is lower than the first temperature range.

20. The memory device of claim 16, wherein the control logic circuit is configured to perform a target refresh operation on a target memory region based on a refresh management command for the target memory region based on activation counts of the plurality of memory regions and the refresh management parameter set.
